(19) United States
(12) Patent Application Publication
(10) Pub. No.: US 2026/0068762 A1
(43) Pub. Date: Mar. 5, 2026

(54) SEMICONDUCTOR PACKAGE AND METHOD OF FABRICATING THE SAME

(71) Applicant: Samsung Electronics Co., Ltd., Suwon-si (KR)

(72) Inventors: Sangho Shin, Suwon-si (KR); Yongjin Park, Suwon-si (KR); Hae-Jung Yu, Suwon-si (KR); Yanggyoo Jung, Suwon-si (KR)

(21) Appl. No.: 19/200,938

(22) Filed: May 7, 2025

(30) Foreign Application Priority Data
Sep. 5, 2024 (KR) 10-2024-0121161

(51) Int. Cl. H01L 25/04; H01L 23/00; H01L 23/31; H01L 23/34; H01L 23/48; H01L 23/544; H01L 23/552

(52) U.S. Cl. CPC H01L 25/04

(57) ABSTRACT

A semiconductor package may include a lower semiconductor chip, a plurality of semiconductor chips stacked on the lower semiconductor chip in a first direction perpendicular to a top surface of the lower semiconductor chip, non-conductive layers between the lower semiconductor chip and a lowermost one of the semiconductor chips and between the semiconductor chips, a mold layer on the semiconductor chips and the non-conductive layers, and a vision layer on the mold layer. The vision layer may include a metallic material, and a bottom surface of the vision layer may be in contact with a top surface of the uppermost one of the semiconductor chips and a top surface of the mold layer.

### CROSS-REFERENCE TO RELATED APPLICATIONS

This U.S. non-provisional patent application claims priority under 35 U.S.C. § 119 to Korean Patent Application No. 10-2024-0121161, filed on Sep. 5, 2024, in the Korean Intellectual Property Office, the entire contents of which are hereby incorporated by reference.

### BACKGROUND OF THE INVENTION

The present disclosure relates to a semiconductor package and a method of fabricating the same, and in particular, to a semiconductor package, on which a plurality of semiconductor chips are mounted, and a method of fabricating the same.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With the development of the electronics industry, there is an increasing demand for small, light, and multifunctional electronic devices. To meet this demand, a multi-chip package technology of mounting a plurality of chips in a single semiconductor package or a system-in-package technology of providing chips of different kinds, which are mounted in a single semiconductor package to serve as a single system, have been proposed.

### SUMMARY

An embodiment of the inventive concept may provide a semiconductor package with high reliability and a method of fabricating the same.

According to an embodiment of the inventive concept, a semiconductor package may include a lower semiconductor chip, a plurality of semiconductor chips stacked on the lower semiconductor chip in a first direction perpendicular to a top surface of the lower semiconductor chip, non-conductive layers between the lower semiconductor chip and a lowermost one of the semiconductor chips and between the semiconductor chips, a mold layer on the semiconductor chips and the non-conductive layers, and a vision layer on the mold layer. The vision layer may include a metallic material, and a bottom surface of the vision layer may be in contact with a top surface of an uppermost one of the semiconductor chips and a top surface of the mold layer.

According to an embodiment of the inventive concept, a semiconductor package may include a first substrate, a unit chip package on the first substrate, and a base chip on the first substrate and spaced apart from the unit chip package. The base chip may be electrically connected to the first substrate through base chip pads and base bumps. The unit chip package may include a lower semiconductor chip, a plurality of semiconductor chips stacked on the lower semiconductor chip in a first direction perpendicular to a top surface of the lower semiconductor chip, non-conductive layers between the semiconductor chips, respectively, a mold layer on the semiconductor chips and the non-conductive layers, and a vision layer on the mold layer. A bottom surface of the vision layer may be in contact with a top surface of an uppermost one of the semiconductor chips, and side surfaces of the first substrate may be spaced apart from side surfaces of the vision layer.

According to an embodiment of the inventive concept, a semiconductor package may include a lower semiconductor chip, a plurality of semiconductor chips stacked on the lower semiconductor chip in a first direction perpendicular to a top surface of the lower semiconductor chip, a plurality of bumps between the semiconductor chips that electrically connect the semiconductor chips to each other, non-conductive layers between the semiconductor chips, each of the non-conductive layers being between corresponding ones of the bumps, which are provided between adjacent ones of the semiconductor chips in the first direction, a mold layer on the semiconductor chips and the non-conductive layers, and a vision layer on the mold layer. The vision layer may include a metallic material, and a bottom surface of the vision layer may be in contact with a top surface of a lowermost one of the semiconductor chips and a top surface of the mold layer. Each of the semiconductor chips may include penetration electrodes, and the semiconductor chips may be electrically connected to each other through the penetration electrodes and the bumps.

### BRIEF DESCRIPTION OF THE DRAWINGS

FIG. 1 is a plan view illustrating a semiconductor package according to an embodiment of the inventive concept.

FIGS. 2A and 2B are sectional views illustrating a semiconductor package according to an embodiment of the inventive concept, taken along a line A-A′ of FIG. 1.

FIGS. 3 to 9 are sectional views illustrating a method of fabricating a semiconductor package, according to an embodiment of the inventive concept.

FIG. 10 is a plan view illustrating a semiconductor package according to an embodiment of the inventive concept.

FIGS. 11A and 11B are sectional views illustrating a semiconductor package according to an embodiment of the inventive concept, taken along a line A-A′ of FIG. 10.

### DETAILED DESCRIPTION

Example embodiments of the inventive concepts will now be described more fully with reference to the accompanying drawings, in which example embodiments are shown. In the drawings, like reference numerals denote like elements, and repeated descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

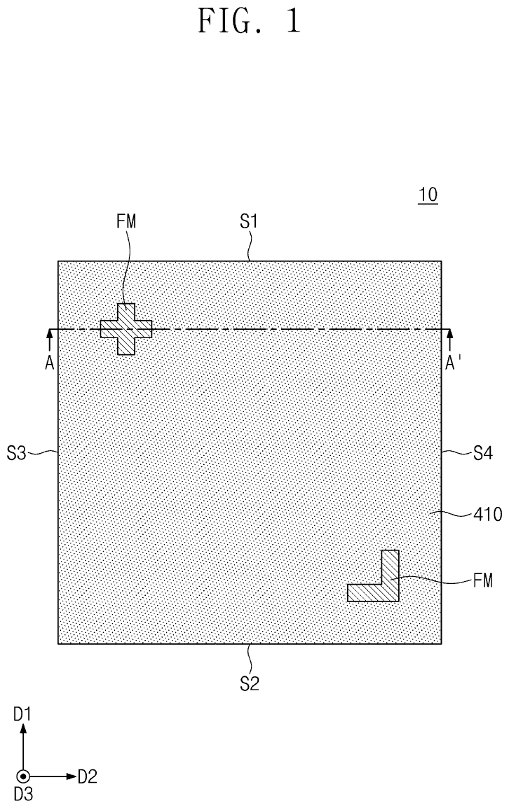

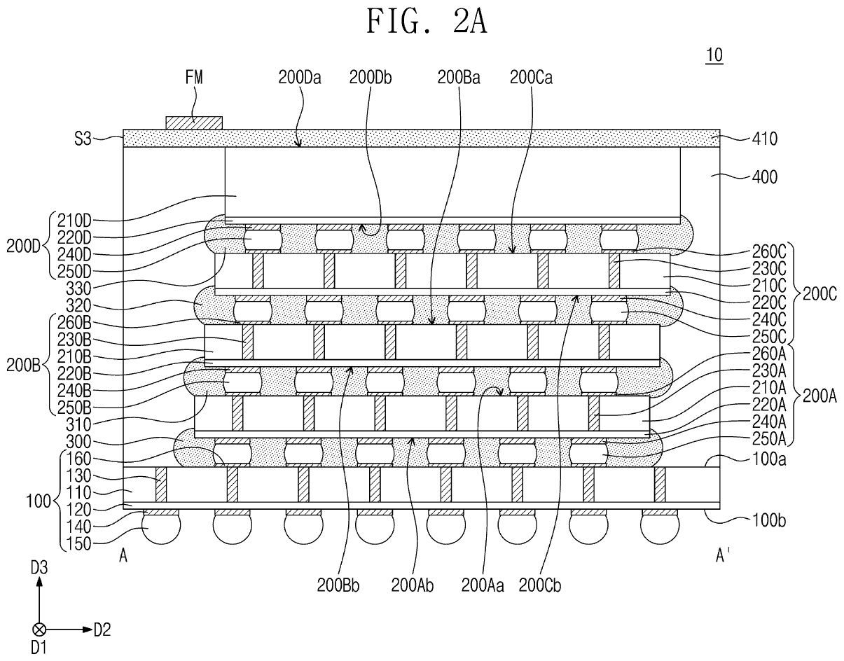

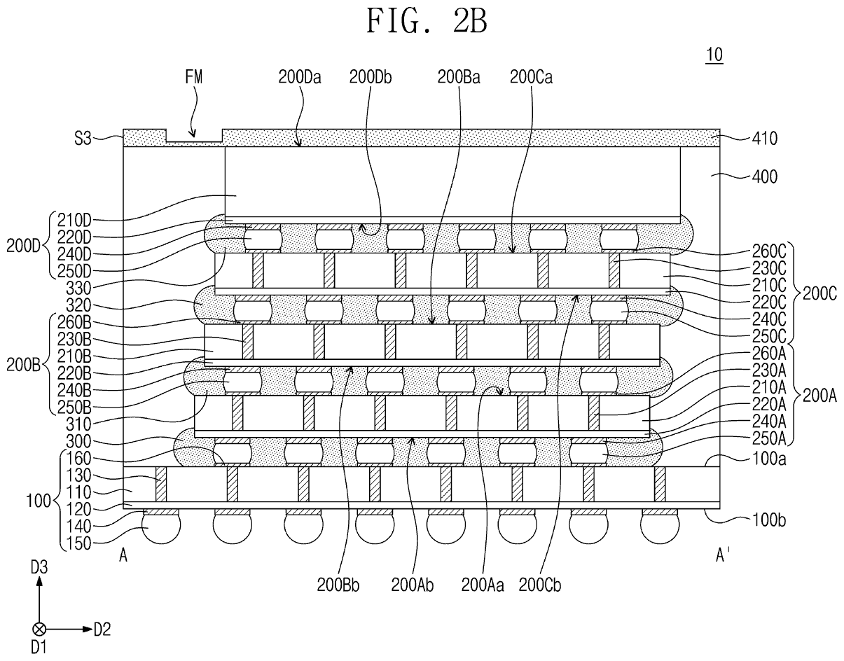

FIG. 1 is a plan view illustrating a semiconductor package according to an embodiment of the inventive concept. FIGS. 2A and 2B are sectional views illustrating a semiconductor package according to an embodiment of the inventive concept, taken along a line A-A′ of FIG. 1.

Referring to FIGS. 1, 2A, and 2B, a semiconductor package 10 may include a lower semiconductor chip 100 and a plurality of semiconductor chips 200A, 200B, 200C, and 200D, which are vertically stacked on the lower semiconductor chip 100. The lower semiconductor chip 100 may have a top surface 100a and a bottom surface 100b, which are opposite to each other in a third direction D3. In the present specification, a first direction D1 and a second direction D2 may be directions that are parallel to the top surface 100a of the lower semiconductor chip 100 and are not parallel to each other. The first direction D1 and the second direction D2 may be referred to as horizontal directions. The third direction D3 may be a vertical direction that is perpendicular to the top surface 100a of the lower semiconductor chip 100. The third direction D3 may be referred to as a vertical direction D3. In an embodiment, the first to third directions D1, D2, and D3 may be orthogonal to each other.

The semiconductor chips 200A, 200B, 200C, and 200D may be disposed on the top surface 100a of the lower semiconductor chip 100 and may be stacked on the lower semiconductor chip 100 in the third direction D3. FIGS. 1, 2A, and 2B illustrate an example, in which four semiconductor chips 200A, 200B, 200C, and 200D are stacked on the lower semiconductor chip 100, but embodiments of the inventive concept are not limited to this example. For example, a plurality of semiconductor chips may be stacked on the lower semiconductor chip 100.

The lower semiconductor chip 100 may include a lower semiconductor substrate 110, a lower circuit layer 120, lower penetration electrodes 130, lower chip pads 140, upper chip pads 160, and lower bumps 150. The lower semiconductor substrate 110 may be a silicon substrate, a germanium substrate, and/or a silicon-germanium substrate. The lower circuit layer 120 may include integrated circuits formed on the lower semiconductor substrate 110. In an embodiment, the lower circuit layer 120 may be adjacent to the bottom surface 100b of the lower semiconductor chip 100.

The lower penetration electrodes 130 may be provided to penetrate or extend through the lower semiconductor substrate 110 and may be horizontally spaced apart from each other in the lower semiconductor substrate 110. The lower penetration electrodes 130 may be electrically connected to the lower circuit layer 120. The lower penetration electrodes 130 may be formed of or include one or more metallic materials (e.g., copper, tungsten, titanium, and tantalum).

The lower chip pads 140 may be disposed on the bottom surface 100b of the lower semiconductor chip 100 and may be electrically connected to the lower circuit layer 120. The lower bumps 150 may be disposed on and electrically connected to the lower chip pads 140, respectively. The lower bumps 150 may be connected to outer terminals. The upper chip pads 160 may be disposed on the top surface 100a of the lower semiconductor chip 100 and may be electrically connected to the lower penetration electrodes 130, respectively. The lower and upper chip pads 140 and 160 may be formed of or include a metallic material (e.g., copper). The lower bumps 150 may include a conductive material and may be provided in the form of at least one of solder balls, bumps, and/or pillars.

The semiconductor chips 200A, 200B, 200C, and 200D may include a first semiconductor chip 200A, a second semiconductor chip 200B, a third semiconductor chip 200C, and a fourth semiconductor chip 200D, which are sequentially stacked on the top surface 100a of the lower semiconductor chip 100 in the third direction D3.

The first semiconductor chip 200A may include a first semiconductor substrate 210A, a first circuit layer 220A, first penetration electrodes 230A, first lower pads 240A, first upper pads 260A, and first bumps 250A. The first semiconductor substrate 210A may be a silicon substrate, a germanium substrate, and/or a silicon-germanium substrate. The first circuit layer 220A may include integrated circuits formed on the first semiconductor substrate 210A. The first semiconductor chip 200A may have a top surface 200Aa and a bottom surface 200Ab, which are opposite to each other in the third direction D3. The first circuit layer 220A may be disposed to be adjacent to the bottom surface 200Ab of the first semiconductor chip 200A.

The first penetration electrodes 230A may be provided to penetrate or extend through the first semiconductor substrate 210A and may be horizontally spaced apart (D2 direction) from each other in the first semiconductor substrate 210A. The first penetration electrodes 230A may be electrically connected to the first circuit layer 220A. The first penetration electrodes 230A may be formed of or include on or more metallic materials (e.g., copper, tungsten, titanium, and tantalum).

The first lower pads 240A may be disposed on the bottom surface 200Ab of the first semiconductor chip 200A and may be electrically connected to the first circuit layer 220A. The first bumps 250A may be disposed on and electrically connected to the first lower pads 240A, respectively. The first bumps 250A may be electrically connected to the upper chip pads 160 of the lower semiconductor chip 100, respectively. The first semiconductor chip 200A may be electrically connected to the lower semiconductor chip 100 through the first lower pads 240A and the first bumps 250A. The first upper pads 260A may be disposed on the top surface 200Aa of the first semiconductor chip 200A and may be electrically connected to the first penetration electrodes 230A, respectively. The first lower pads 240A and the first upper pads 260A may be formed of or include one or more metallic materials (e.g., copper). The first bumps 250A may include a conductive material and may be provided in the form of solder balls, bumps, and/or pillars.

The second semiconductor chip 200B may include a second semiconductor substrate 210B, a second circuit layer 220B, second penetration electrodes 230B, second lower pads 240B, second upper pads 260B, and second bumps 250B. The second semiconductor substrate 210B may be a silicon substrate, a germanium substrate, and/or a silicon-germanium substrate. The second circuit layer 220B may include integrated circuits formed on the second semiconductor substrate 210B. The second semiconductor chip 200B may have a top surface 200Ba and a bottom surface 200Bb, which are opposite to each other in the third direction D3. The second circuit layer 220B may be disposed adjacent to the bottom surface 200Bb of the second semiconductor chip 200B.

The second penetration electrodes 230B may be provided to penetrate or extend through the second semiconductor substrate 210B and may be horizontally spaced apart from each other in the second semiconductor substrate 210B. The second penetration electrodes 230B may be electrically connected to the second circuit layer 220B. The second penetration electrodes 230B may be formed of or include one or more metallic materials (e.g., copper, tungsten, titanium, and tantalum).

The second lower pads 240B may be disposed on the bottom surface 200Bb of the second semiconductor chip 200B and may be electrically connected to the second circuit layer 220B. The second bumps 250B may be disposed on and electrically connected to the second lower pads 240B, respectively. The second bumps 250B may be electrically connected to the first upper pads 260A of the first semiconductor chip 200A, respectively. The second semiconductor chip 200B may be electrically connected to the first semiconductor chip 200A through the second lower pads 240B and the second bumps 250B. The second upper pads 260B may be disposed on the top surface 200Ba of the second semiconductor chip 200B and may be electrically connected to the second penetration electrodes 230B, respectively. The second lower pads 240B and the second upper pads 260B may be formed of or include one or more metallic materials (e.g., copper). The second bumps 250B may include a conductive material and may be provided in the form of at least one of solder balls, bumps, and/or pillars.

The third semiconductor chip 200C may include a third semiconductor substrate 210C, a third circuit layer 220C, third penetration electrodes 230C, third lower pads 240C, third upper pads 260C, and third bumps 250C. The third semiconductor substrate 210C may be a silicon substrate, a germanium substrate, and/or a silicon-germanium substrate. The third circuit layer 220C may include integrated circuits formed on the third semiconductor substrate 210C. The third semiconductor chip 200C may have a top surface 200Ca and a bottom surface 200Cb, which are opposite to each other in the third direction D3. The third circuit layer 220C may be disposed adjacent to the bottom surface 200Cb of the third semiconductor chip 200C.

The third penetration electrodes 230C may be provided to penetrate or extend through the third semiconductor substrate 210C and may be horizontally spaced apart from each other in the third semiconductor substrate 210C. The third penetration electrodes 230C may be electrically connected to the third circuit layer 220C. The third penetration electrodes 230C may be formed of or include one or more metallic materials (e.g., copper, tungsten, titanium, and tantalum).

The third lower pads 240C may be disposed on the bottom surface 200Cb of the third semiconductor chip 200C and may be electrically connected to the third circuit layer 220C. The third bumps 250C may be disposed on and electrically connected to the third lower pads 240C, respectively. The third bumps 250C may be connected to the second upper pads 260B of the second semiconductor chip 200B, respectively. The third semiconductor chip 200C may be electrically connected to the second semiconductor chip 200B through the third lower pads 240C and the third bumps 250C. The third upper pads 260C may be disposed on the top surface 200Ca of the third semiconductor chip 200C and may be electrically connected to the third penetration electrodes 230C, respectively. The third lower pads 240C and the third upper pads 260C may be formed of or include one or more metallic materials (e.g., copper). The third bumps 250C may include a conductive material and may be provided in the form of at least one of solder balls, bumps, and/or pillars.

The fourth semiconductor chip 200D may include a fourth semiconductor substrate 210D, a fourth circuit layer 220D, fourth lower pads 240D, and fourth bumps 250D. The fourth semiconductor chip 200D may be the uppermost one of the semiconductor chips 200A, 200B, 200C, and 200D, and in this case, the fourth semiconductor chip 200D may not include penetration electrodes penetrating or extending through the fourth semiconductor substrate 210D. The fourth semiconductor substrate 210D may be a silicon substrate, a germanium substrate, and/or a silicon-germanium substrate. The fourth circuit layer 220D may include integrated circuits formed on the fourth semiconductor substrate 210D. The fourth semiconductor chip 200D may have a top surface 200Da and a bottom surface 200Db, which are opposite to each other in the third direction D3. The fourth circuit layer 220D may be disposed adjacent to the bottom surface 200Db of the fourth semiconductor chip 200D.

The fourth lower pads 240D may be disposed on the bottom surface 200Db of the fourth semiconductor chip 200D and may be electrically connected to the fourth circuit layer 220D. The fourth bumps 250D may be disposed on and electrically connected to the fourth lower pads 240D, respectively. The fourth bumps 250D may be electrically connected to the third upper pads 260C of the third semiconductor chip 200C, respectively. The fourth semiconductor chip 200D may be electrically connected to the third semiconductor chip 200C through the fourth lower pads 240D and the fourth bumps 250D. The fourth lower pads 240D may be formed of or include one or more metallic materials (e.g., copper). The fourth bumps 250D may include a conductive material and may be provided in the form of at least one of solder balls, bumps, and/or pillars.

The semiconductor chips 200A, 200B, 200C, and 200D may be memory chips. The semiconductor chips 200A, 200B, 200C, and 200D may be semiconductor chips of the same kind, and in an embodiment, they may be memory chips of the same kind. The lower semiconductor chip 100 may be a memory chip, a logic chip, an application processor (AP) chip, or a system-on-chip (SOC). The semiconductor chips 200A, 200B, 200C, and 200D and the lower semiconductor chip 100 may be electrically connected to each other and may constitute a high bandwidth memory (HBM) chip.

The semiconductor package 10 may further include non-conductive layers 300, 310, 320, and 330, which are respectively interposed between the lowermost one (i.e., the first semiconductor chip 200A) of the semiconductor chips 200A, 200B, 200C, and 200D and the lower semiconductor chip 100 and between the semiconductor chips 200A, 200B, 200C, and 200D.

The non-conductive layers 300, 310, 320, and 330 may include a first non-conductive layer 300 between the lower semiconductor chip 100 and the first semiconductor chip 200A, a second non-conductive layer 310 between the first and second semiconductor chips 200A and 200B, a third non-conductive layer 320 between the second semiconductor chip 200B and the third semiconductor chip 200C, and a fourth non-conductive layer 330 between the third semiconductor chip 200C and the fourth semiconductor chip 200D.

The first non-conductive layer 300 may be interposed between the top surface 100a of the lower semiconductor chip 100 and the bottom surface 200Ab of the first semiconductor chip 200A and between the first bumps 250A. The first non-conductive layer 300 may at least partially fill a space between the first bumps 250A. The first non-conductive layer 300 may extend into a space between the upper chip pads 160 to contact the top surface 100a of the lower semiconductor chip 100 and may extend into a space between the first lower pads 240A to contact the bottom surface 200Ab of the first semiconductor chip 200A. The first semiconductor chip 200A may be attached to the lower semiconductor chip 100 by the first non-conductive layer 300. The first non-conductive layer 300 may include a protruding portion, which protrudes from a side surface of the first semiconductor chip 200A. The protruding portion of the first non-conductive layer 300 may at least partially cover a portion of the side surface of the first semiconductor chip 200A. In other words, the first semiconductor chip 200A may have a structure that is partially inserted in an upper portion of the first non-conductive layer 300. However, embodiments of the inventive concept are not limited to this example.

The second non-conductive layer 310 may be interposed between the top surface 200Aa of the first semiconductor chip 200A and the bottom surface 200Bb of the second semiconductor chip 200B and between the second bumps 250B. The second non-conductive layer 310 may at least partially fill a space between the second bumps 250B. The second non-conductive layer 310 may extend into a space between the first upper pads 260A to contact the top surface 200Aa of the first semiconductor chip 200A and may extend into a space between the second lower pads 240B to contact the bottom surface 200Bb of the second semiconductor chip 200B. The second semiconductor chip 200B may be attached to the first semiconductor chip 200A by the second non-conductive layer 310. The second non-conductive layer 310 may include a protruding portion, which protrudes from a side surface of the second semiconductor chip 200B. The protruding portion of the second non-conductive layer 310 may be on and at least partially cover a portion of the side surface of each of the first and second semiconductor chips 200A and 200B. In other words, the second semiconductor chip 200B may have a structure that is partially inserted in an upper portion of the second non-conductive layer 310. However, embodiments of the inventive concept are not limited to this example.

In an embodiment, the side surfaces of the second semiconductor chip 200B may not be vertically aligned to the side surfaces of the first semiconductor chip 200A. When viewed in a plan view, the first and second semiconductor chips 200A and 200B may not fully overlap each other in the vertical direction (D3 direction). When viewed in a plan view, the first and second semiconductor chips 200A and 200B may partially overlap each other in the vertical direction. In another embodiment, unlike the illustrated example, the side surfaces of the first semiconductor chip 200A may be aligned to the side surfaces of the second semiconductor chip 200B in the vertical direction (D3 direction). When viewed in a plan view, the first and second semiconductor chips 200A and 200B may fully overlap each other in the vertical direction (D3 direction).

The third non-conductive layer 320 may be interposed between the top surface 200Ba of the second semiconductor chip 200B and the bottom surface 200Cb of the third semiconductor chip 200C and between the third bumps 250C. The third non-conductive layer 320 may at least partially fill a space between the third bumps 250C. The third non-conductive layer 320 may extend into a space between the second upper pads 260B to contact the top surface 200Ba of the second semiconductor chip 200B and may extend into a space between the third lower pads 240C to contact the bottom surface 200Cb of the third semiconductor chip 200C. The third semiconductor chip 200C may be attached to the second semiconductor chip 200B by the third non-conductive layer 320. The third non-conductive layer 320 may include a protruding portion, which protrudes from a side surface of the third semiconductor chip 200C. The protruding portion of the third non-conductive layer 320 may be on and at least partially cover a portion of the side surface of each of the second and third semiconductor chips 200B and 200C. In other words, the third semiconductor chip 200C may have a structure that is partially inserted in an upper portion of the third non-conductive layer 320. However, embodiments of the inventive concept are not limited to this example.

In an embodiment, the side surfaces of the third semiconductor chip 200C may not be aligned to the side surfaces of the first and second semiconductor chips 200A and 200B in the vertical direction (D3 direction). When viewed in a plan view, the first semiconductor chip 200A, the second semiconductor chip 200B, and the third semiconductor chip 200C may not fully overlap each other in the vertical direction (D3 direction). When viewed in a plan view, the first semiconductor chip 200A, the second semiconductor chip 200B, and the third semiconductor chip 200C may partially overlap each other in the vertical direction (D3 direction). In another embodiment, unlike the illustrated example, the side surfaces of the first and second semiconductor chips 200A and 200B may be vertically aligned to the side surfaces of the third semiconductor chip 200C. When viewed in a plan view, the first to third semiconductor chips 200A, 200B, and 200C may fully overlap each other in the vertical direction (D3 direction).

The fourth non-conductive layer 330 may be interposed between the top surface 200Ca of the third semiconductor chip 200C and the bottom surface 200Db of the fourth semiconductor chip 200D and between the fourth bumps 250D. The fourth non-conductive layer 330 may at least partially fill a space between the fourth bumps 250D. The fourth non-conductive layer 330 may extend into a space between the third upper pads 260C to contact the top surface 200Ca of the third semiconductor chip 200C and may extend into a space between the fourth lower pads 240D to contact the bottom surface 200Db of the fourth semiconductor chip 200D. The fourth semiconductor chip 200D may be attached to the third semiconductor chip 200C by the fourth non-conductive layer 330. The fourth non-conductive layer 330 may include a protruding portion, which protrudes from a side surface of the fourth semiconductor chip 200D. The protruding portion of the fourth non-conductive layer 330 may be on and at least partially cover a portion of the side surface of each of the third and fourth semiconductor chips 200C and 200D. In other words, the fourth semiconductor chip 200D may have a structure that is partially inserted in an upper portion of the fourth non-conductive layer 330. However, embodiments of the inventive concept are not limited to this example.

In an embodiment, the side surfaces of the fourth semiconductor chip 200D may not be aligned to the side surfaces of the first to third semiconductor chips 200A, 200B, and 200C in the vertical direction (D3 direction). When viewed in a plan view, the first semiconductor chip 200A, the second semiconductor chip 200B, the third semiconductor chip 200C, and the fourth semiconductor chip 200D may not fully overlap each other in the vertical direction (D3 direction). When viewed in a plan view, the first semiconductor chip 200A, the second semiconductor chip 200B, the third semiconductor chip 200C, and the fourth semiconductor chip 200D may partially overlap each other in the vertical direction (D3 direction). In another embodiment, unlike the illustrated example, the side surfaces of the first to second semiconductor chips 200A, 200B, and 200C may be vertically aligned to the side surfaces of the fourth semiconductor chip 200D. When viewed in a plan view, the first to fourth semiconductor chips 200A, 200B, 200C, and 200D may fully overlap each other in the vertical direction (D4 direction).

The protruding portions of the first to fourth non-conductive layers 300, 310, 320, and 330 may be spaced apart from each other in the third direction D3.

The non-conductive layers 300, 310, 320, and 330 may be formed of or include the same material. The non-conductive layers 300, 310, 320, and 330 may include one or more thermosetting polymer resins (e.g., bisphenol-type epoxy resin, novolac-type epoxy resin, phenolic resin, urea resin, melamine resin, unsaturated polyester resin, and/or resorcinol resin).

A mold layer 400 may be disposed on the lower semiconductor chip 100. The mold layer 400 may be on and at least partially cover side surfaces of the semiconductor chips 200A, 200B, 200C, and 200D. The mold layer 400 may be on and at least partially cover the protruding portions, which are the side surfaces of the non-conductive layers 300, 310, 320, and 330. The mold layer 400 may extend from the top surface 100a of the lower semiconductor chip 100 to the top surface 200Da of the uppermost one (e.g., the fourth semiconductor chip 200D) of the semiconductor chips 200A, 200B, 200C, and 200D. The mold layer 400 may at least partially expose the top surface 200Da of the uppermost one (e.g., the fourth semiconductor chip 200D) of the semiconductor chips 200A, 200B, 200C, and 200D. A top surface of the mold layer 400 may be coplanar with the top surface 200Da of the fourth semiconductor chip 200D.

The mold layer 400 may be formed of or include an insulating material (e.g., an epoxy molding compound (EMC)).

A vision layer 410 may be disposed on the mold layer 400. A bottom surface of the vision layer 410 may be in contact with the top surface 200Da of the uppermost one (e.g., the fourth semiconductor chip 200D) of the semiconductor chips 200A, 200B, 200C, and 200D. In addition, the bottom surface of the vision layer 410 may be in contact with the top surface of the mold layer 400. The vision layer 410 may be on and at least partially cover the entire top surface of the lower semiconductor chip 100.

The vision layer 410 may include an electromagnetic interference shielding material and/or a thermally conductive material. The vision layer 410 may be formed of or include one or more metallic materials. For example, the vision layer 410 may be formed of or include at least one of Cu, Al, and/or Ag, but embodiments of the inventive concept are not limited to these examples.

A reference mark FM may be disposed on the vision layer 410. When viewed in a plan view, the reference mark FM may be disposed adjacent to an edge of the vision layer 410. In detail, the vision layer 410 may have a first side surface S1 and a second side surface S2, which are opposite to each other in the first direction D1. In addition, the vision layer 410 may have a third side surface S3 and a fourth side surface S4, which are opposite to each other in the second direction D2. In an embodiment, the reference mark FM may be disposed in an edge region of the vision layer 410 adjacent to the first and third side surfaces S1 and S3. In an embodiment, a plurality of reference marks FM may be provided. The reference marks FM may be respectively disposed adjacent to the edges of the vision layer 410. As an example, the reference marks FM may be respectively disposed in edge regions of the vision layer 410, which are adjacent to the first and third side surfaces S1 and S3 and adjacent to the second and fourth side surfaces S2 and S4.

In an embodiment, as shown in FIG. 2A, the reference mark FM may be formed in an embossed manner, and in this case, the reference mark FM may have a shape protruding from the vision layer 410. The reference mark FM may be formed of or include one or more metallic materials (e.g., Cu, Al, Ni, and/or Au). In another embodiment, as shown in FIG. 2B, the reference mark FM may be formed in an intaglio manner. An empty region, which is used as the reference mark FM, may be formed in the vision layer 410. The reference mark FM may not be limited to a specific shape. For example, as shown in FIG. 1, the reference mark FM may be provided to have a cross shape or a ‘L’ shape, but embodiments of the inventive concept are not limited to these examples.

In the case of a thermal compression nonconductive film (TC-NCF) method is used, there may be a bond slip issue in a specific direction, in a process of stacking the semiconductor chips. As a result, the semiconductor chips in the semiconductor package may have an asymmetrically stacked structure. This may lead to a difference in an amount of the mold layer 400, which is formed on the side surfaces of the semiconductor chips. In this case, it may be difficult to recognize the relative position between the semiconductor package and the interposer substrate, when an inspection apparatus (e.g., vision) is used to accurately mount the semiconductor package on an interposer substrate.

According to an embodiment of the inventive concept, even when a plurality of semiconductor chips are stacked in an asymmetric shape, the vision layer 410 may be easily recognized by the inspection apparatus, and the relative position between the semiconductor package and the interposer substrate may be easily examined through the vision layer 410. As an example, it may be possible to accurately examine the positions of the side surfaces of the vision layer 410, and thus, the semiconductor package may be accurately mounted on the interposer substrate. In addition, it may be possible to accurately examine the height of the top surface of the vision layer 410, and thus, the semiconductor package may be more accurately mounted on a desired position on the interposer substrate. In other words, by measuring the position of the side or top surface of the vision layer 410, it may be possible to find the position of the semiconductor package to be mounted on the interposer substrate. Thus, the semiconductor package may be fabricated to have high reliability. In addition, the vision layer 410 may include an electromagnetic interference shielding material and/or a thermally conductive material. Thus, it may be possible to improve the heat-dissipation property of the semiconductor package and to realize the stable electromagnetic interference shielding property.

In addition, the reference mark FM disposed on the vision layer 410 may be used to find the position of the semiconductor package to be mounted on the interposer substrate. Since the reference mark FM is easily recognized by the inspection apparatus, the reference mark FM may make it possible to easily recognize the relative position between the semiconductor package and the interposer substrate. As an example, the position of the reference mark FM may be accurately examined by the inspection apparatus, and information on the position of the reference mark FM may be used to accurately mount the semiconductor package on the interposer substrate.

In addition, because the vision layer 410 may, in some embodiments, cover the entire top surface of the semiconductor package 10, the mold layer 400, which is asymmetrically provided, may be veiled by the vision layer 410. Thus, it may be possible to provide a semiconductor package with an aesthetically improved appearance.

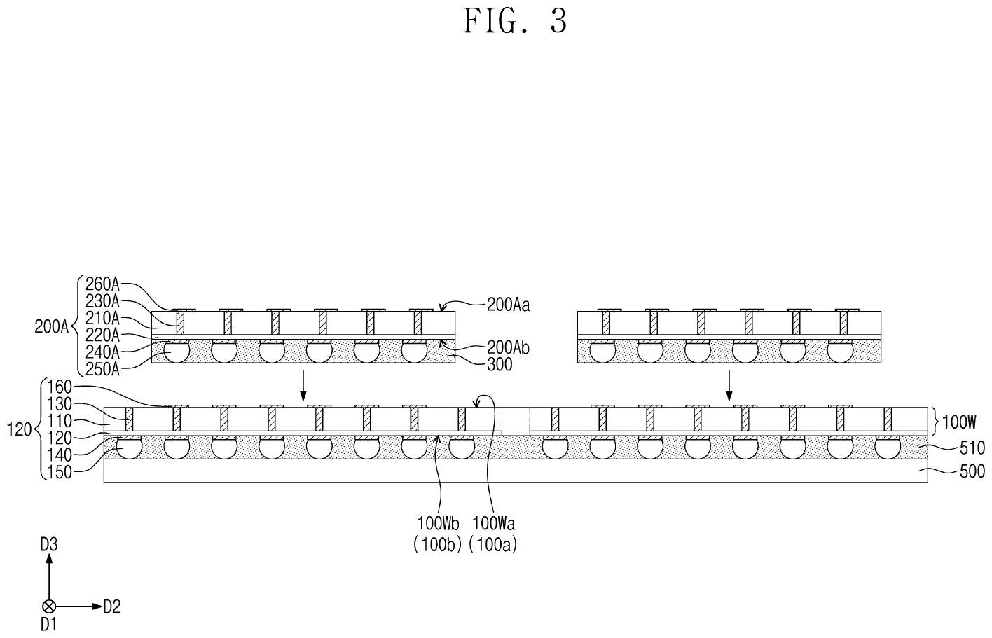

FIGS. 3 to 9 are sectional views illustrating a method of fabricating a semiconductor package, according to an embodiment of the inventive concept. For concise description, features described previously with respect to the semiconductor package of FIGS. 1, 2A, and 2B will be omitted.

Referring to FIG. 3, a lower substrate 100W including a plurality of lower semiconductor chips 100 may be provided. The lower substrate 100W may have a top surface 100Wa and a bottom surface 100Wb, which are opposite to each other in the third direction D3. The top surface 100Wa of the lower substrate 100W may correspond to the top surfaces 100a of the lower semiconductor chips 100, and the bottom surface 100Wb of the lower substrate 100W may correspond to the bottom surfaces 100b of the lower semiconductor chips 100. The lower semiconductor chips 100 may be arranged in a direction (e.g., the second direction D2) parallel to the top surface 100Wa of the lower substrate 100W. Each of the lower semiconductor chips 100 may include the lower semiconductor substrate 110, the lower circuit layer 120, the lower penetration electrodes 130, the lower chip pads 140, the upper chip pads 160, and the lower bumps 150 described with reference to FIGS. 1, 2A, and 2B.

The lower substrate 100W may be provided on a carrier substrate 500. The lower substrate 100W may be provided in such a way that the bottom surface 100Wb of the lower substrate 100W faces the carrier substrate 500. An adhesive layer 510 may be provided between the bottom surface 100Wb of the lower substrate 100W and the carrier substrate 500 and may be interposed between the lower bumps 150. The lower substrate 100W may be attached to the carrier substrate 500 by the adhesive layer 510.

The first semiconductor chips 200A may be provided on the top surface 100Wa of the lower substrate 100W and may be provided on the lower semiconductor chips 100, respectively. Each of the first semiconductor chips 200A may have the top surface 200Aa and the bottom surface 200Ab, which are opposite to each other in the third direction D3. Each of the first semiconductor chips 200A may be provided in such a way that the bottom surface 200Ab faces the top surface 100a of each of the lower semiconductor chips 100. Each of the first semiconductor chips 200A may include the first semiconductor substrate 210A, the first circuit layer 220A, the first penetration electrodes 230A, the first lower pads 240A, the first upper pads 260A, and the first bumps 250A described with reference to FIGS. 1, 2A, and 2B.

The first non-conductive layer 300 may be provided on the bottom surface 200Ab of each of the first semiconductor chips 200A. The first non-conductive layer 300 may be on and at least partially cover the bottom surface 200Ab of each of the first semiconductor chips 200A and the first bumps 250A and may at least partially fill a space between the first bumps 250A.

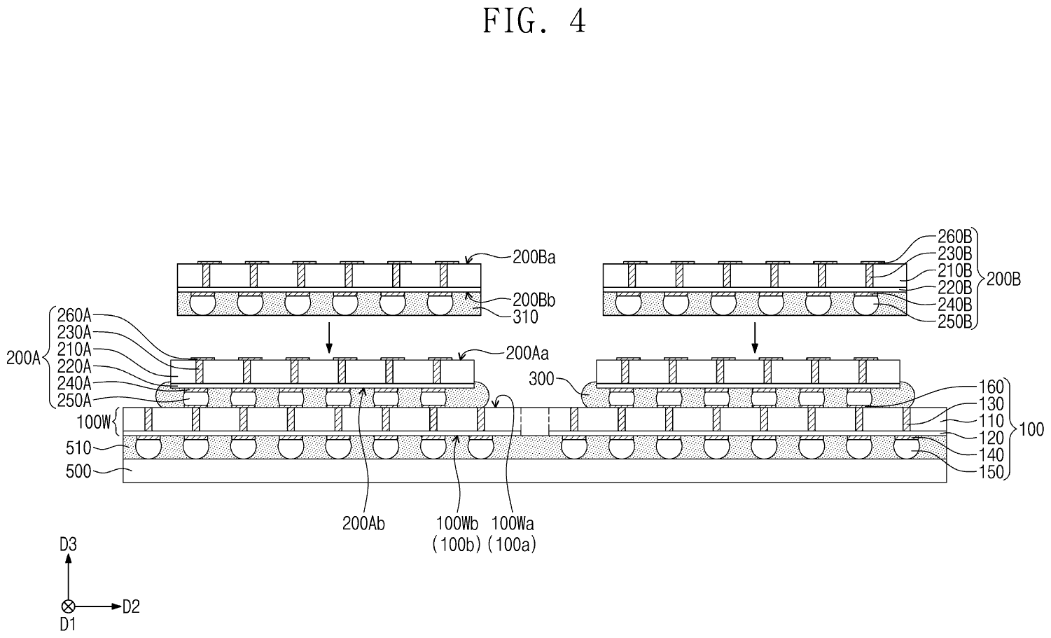

Referring to FIG. 4, the first semiconductor chips 200A may be bonded to the lower semiconductor chips 100, respectively, through a thermo-compression process. The first bumps 250A of the first semiconductor chips 200A may be respectively connected to the upper chip pads 160 of the lower semiconductor chips 100. The first non-conductive layer 300 may be interposed between the top surface 100a of each of the lower semiconductor chips 100 and the bottom surface 200Ab of each of the first semiconductor chips 200A and between the first bumps 250A. Each of the first semiconductor chips 200A may be attached to a corresponding one of the lower semiconductor chips 100 by the first non-conductive layer 300.

The first non-conductive layer 300 may be overflown during the process of bonding the first semiconductor chips 200A to the lower semiconductor chips 100, and thus, a portion of the first non-conductive layer 300 may protrude from the side surface of each of the first semiconductor chips 200A. In other words, a portion of the first non-conductive layer 300 may extend to regions on the side surface of each of the first semiconductor chips 200A and the top surface 100a of each of the lower semiconductor chips 100. The first non-conductive layer 300 may be on and at least partially cover a portion of the side surface of each of the first semiconductor chips 200A.

The second semiconductor chips 200B may be provided on the top surface 100Wa of the lower substrate 100W and may be provided on the first semiconductor chips 200A, respectively. Each of the second semiconductor chips 200B may have the top surface 200Ba and the bottom surface 200Bb, which are opposite to each other in the third direction D3. Each of the second semiconductor chips 200B may be provided in such a way that the bottom surface 200Bb thereof faces the top surface 200Aa of each of the first semiconductor chips 200A. Each of the second semiconductor chips 200B may include the second semiconductor substrate 210B, the second circuit layer 220B, the second penetration electrodes 230B, the second lower pads 240B, the second upper pads 260B, and the second bumps 250B described with reference to FIGS. 1, 2A, and 2B.

The second non-conductive layer 310 may be provided on the bottom surface 200Bb of each of the second semiconductor chips 200B. The second non-conductive layer 310 may be on and at least partially cover the bottom surface 200Bb of each of the second semiconductor chips 200B and the second bumps 250B and may at least partially fill a space between the second bumps 250B.

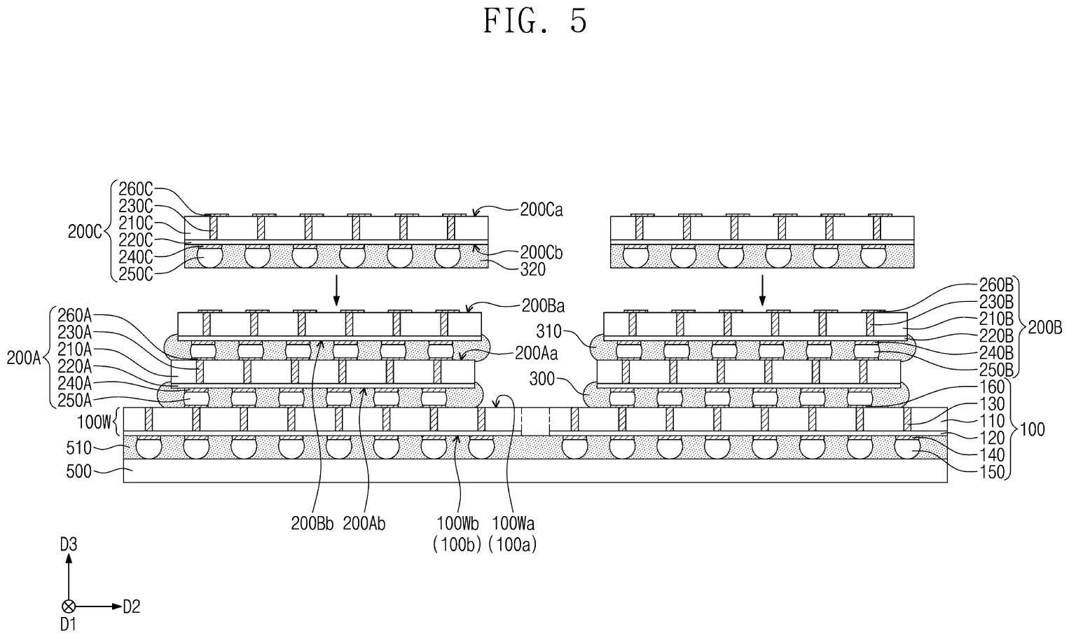

Referring to FIG. 5, the second semiconductor chips 200B may be bonded to the first semiconductor chips 200A, respectively, through a thermo-compression process. The second bumps 250B of the second semiconductor chips 200B may be respectively electrically connected to the first upper pads 260A of the first semiconductor chips 200A. The second non-conductive layer 310 may be interposed between the top surface 200Aa of each of the first semiconductor chips 200A and the bottom surface 200Bb of each of the second semiconductor chips 200B and between the second bumps 250B. Each of the second semiconductor chips 200B may be attached to a corresponding one of the first semiconductor chips 200A by the second non-conductive layer 310.

During the bonding process between the first and second semiconductor chips 200A and 200B, a slip issue may occur in a specific direction. In an embodiment, each of the second semiconductor chips 200B may be slipped from each of the first semiconductor chips 200A in the second direction D2. Thus, the side surface of each of the first semiconductor chips 200A may not be aligned to the side surface of each of the second semiconductor chips 200B in the third direction D3. In other words, the side surface of each of the first semiconductor chips 200A and the side surface of each of the second semiconductor chips 200B may be horizontally spaced apart from each other, e.g., spaced apart in the D2 direction. However, embodiments of the inventive concept are not limited to this example.

During the bonding process between the first and second semiconductor chips 200A and 200B, the second non-conductive layer 310 may be overflown, and thus, a portion of the second non-conductive layer 310 may protrude from the side surface of each of the second semiconductor chips 200B. A portion of the second non-conductive layer 310 may extend to regions on the side surface of each of the second semiconductor chips 200B and the side surface of each of the first semiconductor chips 200A. In other words, a portion of the second non-conductive layer 310 may be on and at least partially cover a portion of the side surface of each of the first and second semiconductor chips 200A and 200B.

The third semiconductor chips 200C may be provided on the top surface 100Wa of the lower substrate 100W and may be provided on the second semiconductor chips 200B, respectively. Each of the third semiconductor chips 200C may have the top surface 200Ca and the bottom surface 200Cb, which are opposite to each other in the third direction D3, and each of the third semiconductor chips 200C may be provided in such a way that the bottom surface 200Cb thereof faces the top surface 200Ba of a corresponding one of the second semiconductor chips 200B. Each of the third semiconductor chips 200C may include the third semiconductor substrate 210C, the third circuit layer 220C, the third penetration electrodes 230C, the third lower pads 240C, the third upper pads 260C, and the third bumps 250C described with reference to FIGS. 1, 2A, and 2B. The third non-conductive layer 320 may be on and at least partially cover the bottom surface 200Cb of each of the third semiconductor chips 200C and the third bumps 250C and may a least partially fill a space between the third bumps 250C.

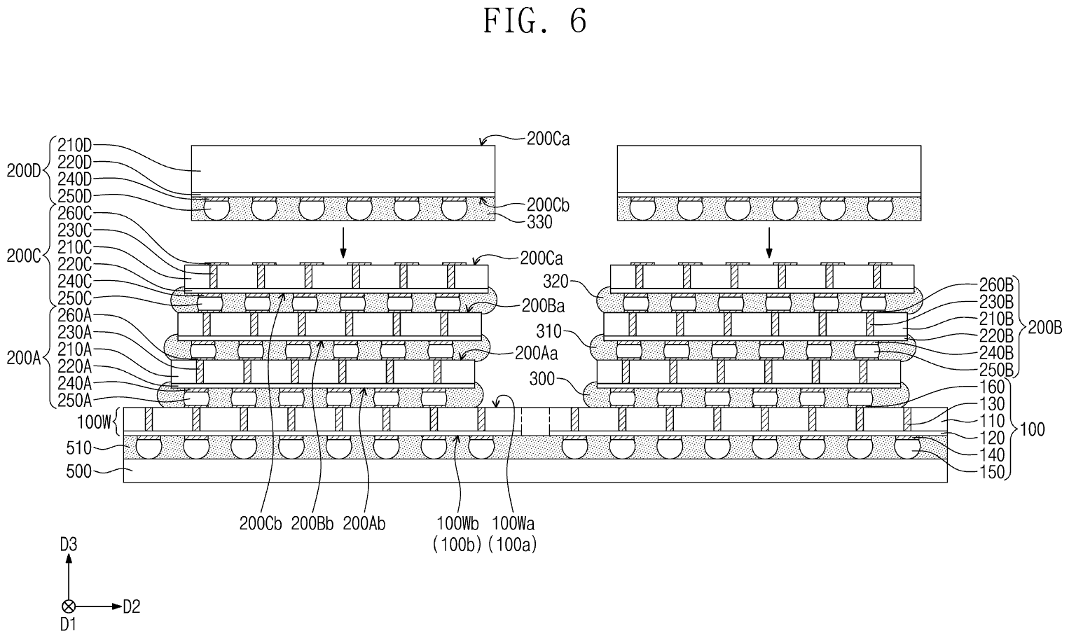

Referring to FIG. 6, the third semiconductor chips 200C may be bonded to the second semiconductor chips 200B, respectively, through a thermo-compression process. The third bumps 250C of each of the third semiconductor chips 200C may be respectively electrically connected to the second upper pads 260B of each of the second semiconductor chips 200B. The third non-conductive layer 320 may be interposed between the top surface 200Ba of each of the second semiconductor chips 200B and the bottom surface 200Cb of each of the third semiconductor chips 200C and between the third bumps 250C. Each of the third semiconductor chips 200C may be attached to a corresponding one of the second semiconductor chips 200B by the third non-conductive layer 320.

During the bonding process between the second and third semiconductor chips 200B and 200C, a slip issue may occur in a specific direction. In an embodiment, each of the third semiconductor chips 200C may be slipped from each of the second semiconductor chips 200B in the second direction D2. Thus, the side surface of each of the second semiconductor chips 200B and the side surface of each of the third semiconductor chips 200C may not be aligned to each other in the third direction D3. That is, the side surface of each of the second semiconductor chips 200B may be horizontally spaced apart from the side surface of each of the third semiconductor chips 200C. However, embodiments of the inventive concept are not limited to this example.

During the bonding process between the second and third semiconductor chips 200B and 200C, the third non-conductive layer 320 may be overflown, and thus, a portion of the third non-conductive layer 320 may protrude from the side surface of each of the third semiconductor chips 200C. A portion of the third non-conductive layer 320 may extend to regions on the side surface of each of the third semiconductor chips 200C and the side surface of each of the second semiconductor chips 200B. In other words, a portion of the third non-conductive layer 320 may be on and at least partially cover a portion of the side surface of each of the second and third semiconductor chips 200B and 200C.

The fourth semiconductor chips 200D may be provided on the top surface 100Wa of the lower substrate 100W and may be provided on the third semiconductor chips 200C, respectively. Each of the fourth semiconductor chips 200D may have the top surface 200Da and the bottom surface 200Db, which are opposite to each other in the third direction D3, and may be provided in such a way that the bottom surface 200Db thereof faces the top surface 200Ca of each of the third semiconductor chips 200C. Each of the fourth semiconductor chips 200D may include the fourth semiconductor substrate 210D, the fourth circuit layer 220D, the fourth lower pads 240D, and the fourth bumps 250D described with reference to FIGS. 1, 2A, and 2B. The fourth non-conductive layer 330 may be on and at least partially cover the bottom surface 200Db of each of the fourth semiconductor chips 200D and the fourth bumps 250D and may at least partially fill a space between the fourth bumps 250D.

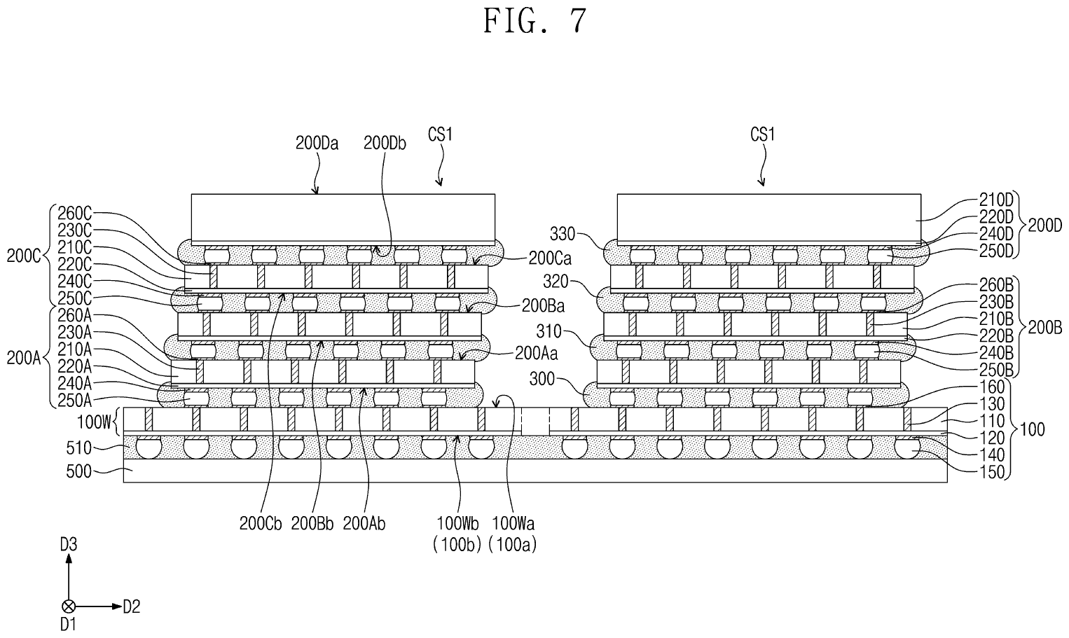

Referring to FIG. 7, the fourth semiconductor chips 200D may be bonded to the third semiconductor chips 200C, respectively, through a thermo-compression process. The fourth bumps 250D of the fourth semiconductor chips 200D may be respectively electrically connected to the third upper pads 260C of the third semiconductor chips 200C. The fourth non-conductive layer 330 may be interposed between the top surface 200Ca of each of the third semiconductor chips 200C and the bottom surface 200Db of each of the fourth semiconductor chips 200D and between the fourth bumps 250D. Each of the fourth semiconductor chips 200D may be attached to a corresponding one of the third semiconductor chips 200C by the fourth non-conductive layer 330.

During the bonding process between the third and fourth semiconductor chips 200C and 200D, a slip issue may occur in a specific direction. In an embodiment, each of the fourth semiconductor chips 200D may be slipped from each of the third semiconductor chips 200C in the second direction D2. Accordingly, the side surface of each of the third semiconductor chips 200C and the side surface of each of the fourth semiconductor chips 200D may not be aligned to each other in the third direction D3. That is, the side surface of each of the third semiconductor chips 200C and the side surface of each of the fourth semiconductor chips 200D may be horizontally spaced apart from each other. However, embodiments of the inventive concept are not limited to this example.

During the bonding process between the third and fourth semiconductor chips 200C and 200D, the fourth non-conductive layer 330 may be overflown, and thus, a portion of the fourth non-conductive layer 330 may protrude from the side surface of each of the fourth semiconductor chips 200D. A portion of the fourth non-conductive layer 330 may be extended to regions on the side surface of each of the fourth semiconductor chips 200D and the side surface of each of the third semiconductor chips 200C. In other words, a portion of the fourth non-conductive layer 330 may at least partially cover a portion of the side surface of each of the third and fourth semiconductor chips 200C and 200D.

Because the first to fourth semiconductor chips 200A, 200B, 200C, and 200D are provided to the lower semiconductor chips 100, a plurality of first chip stacks CS1 may be respectively mounted on the lower semiconductor chips 100. Each of the first chip stacks CS1 may include the first to fourth semiconductor chips 200A, 200B, 200C, and 200D, which are stacked on each of the lower semiconductor chips 100. Each of the first chip stacks CS1 may further include the first to fourth non-conductive layers 300, 310, 320, and 330, which are interposed between each of the lower semiconductor chips 100 and the corresponding one of the first semiconductor chips 200A and between the corresponding ones of the first to fourth semiconductor chips 200A, 200B, 200C, and 200D.

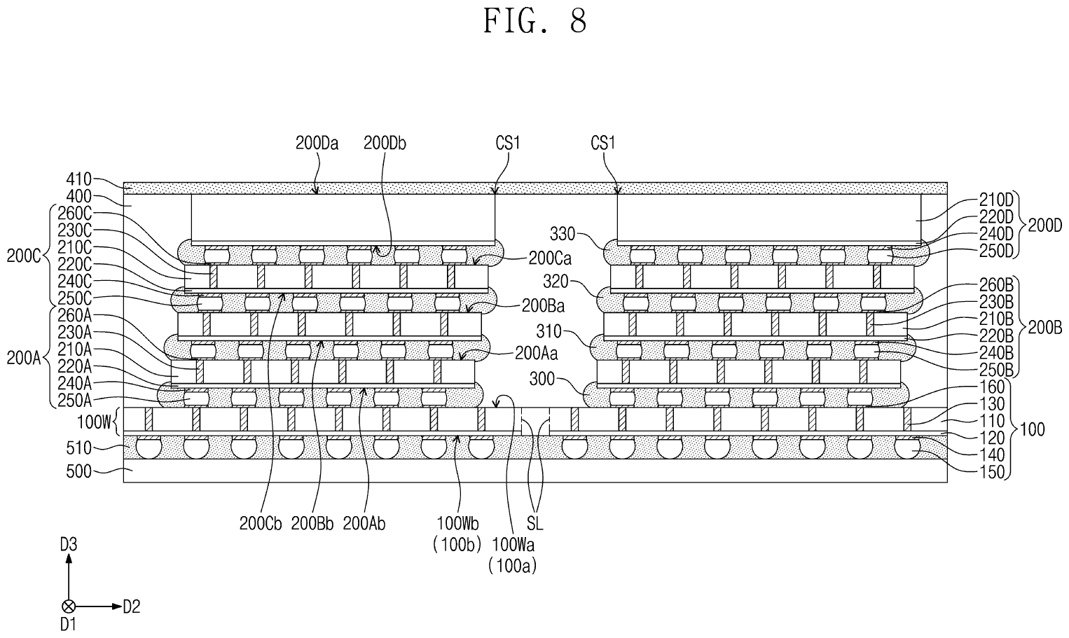

Referring to FIG. 8, the mold layer 400 may be formed on the top surface 100Wa of the lower substrate 100W. The mold layer 400 may be on and at least partially cover the first chip stacks CS1. The mold layer 400 may be interposed between the first chip stacks CS1 to at least partially fill a space between the first chip stacks CS1. In an embodiment, the mold layer 400 may be ground until the top surface of each of the first chip stacks CS1 is exposed. The top surface of each of the first chip stacks CS1 may correspond to the top surface of the uppermost one of the semiconductor chips (e.g., the top surface 200Da of the fourth semiconductor chip 200D).

Next, the vision layer 410 may be formed on the mold layer 400. The vision layer 410 may be formed, in some embodiments, to cover the entire top surface of the lower substrate 100W. The vision layer 410 may be formed by a physical vapor deposition (PVD) process (e.g., a sputtering coating process).

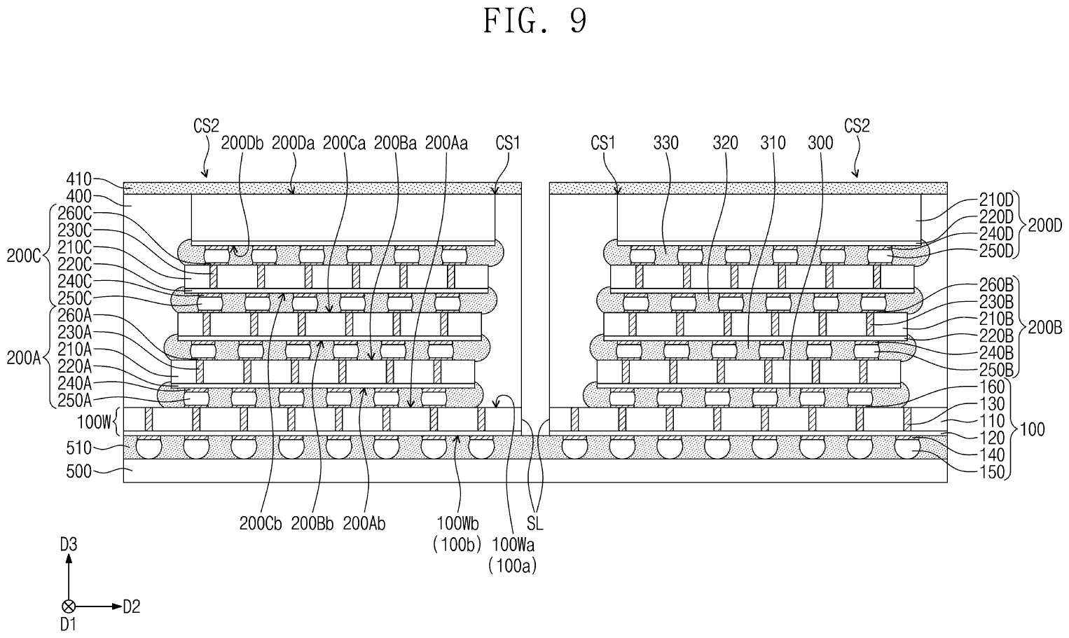

Referring to FIGS. 8 and 9, a singulation process may be performed on the vision layer 410, the mold layer 400, and the lower substrate 100W to form semiconductor packages separated from each other. For example, a sawing process may be performed along a sawing line SL. The sawing process may be performed to cut the vision layer 410, the mold layer 400, and the lower substrate 100W between the first chip stacks CS1. The semiconductor package may be divided into a plurality of second chip stacks CS2 by the sawing process. Each of the second chip stacks CS2 may include the first chip stack CS1, the mold layer 400, and the vision layer 410.

Referring back to FIGS. 1, 2A, and 2B, the carrier substrate 500 and the adhesive layer 510 may be removed. In addition, the reference mark FM may be formed on the vision layer 410. In an embodiment, the reference mark FM may be formed in an embossed manner. The process in the embossed manner may include forming a metal layer (not shown) on the vision layer 410 and patterning the metal layer. In an embodiment, the reference mark FM may be formed in an intaglio manner. The process in the intaglio manner may include patterning the vision layer 410.

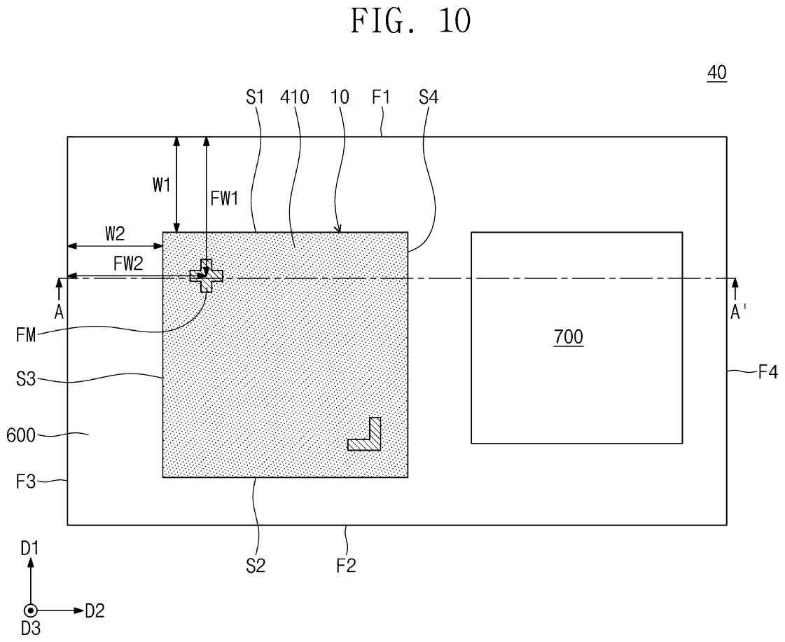

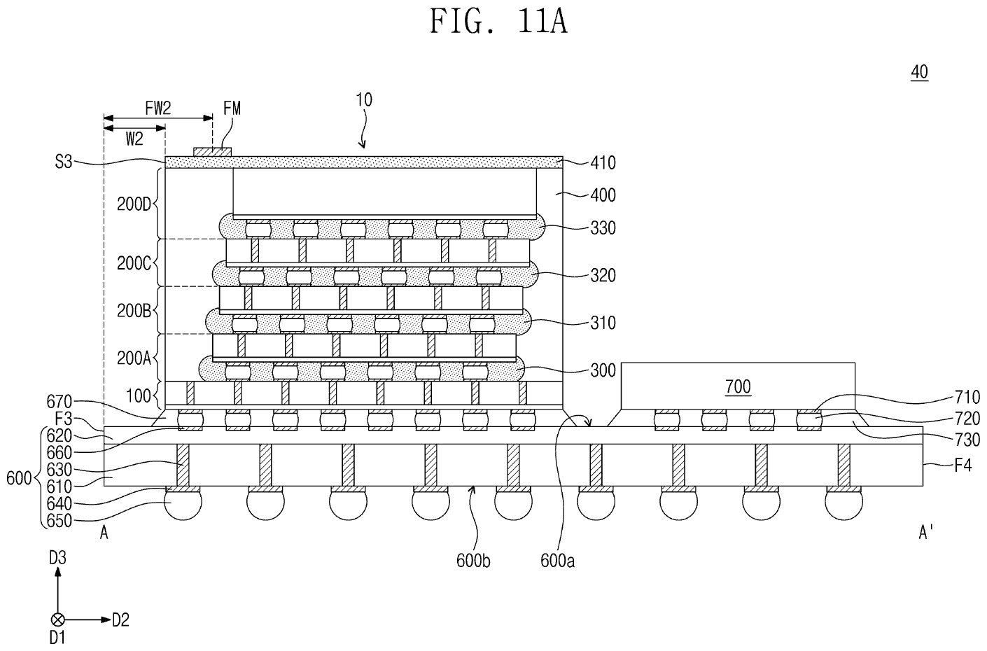

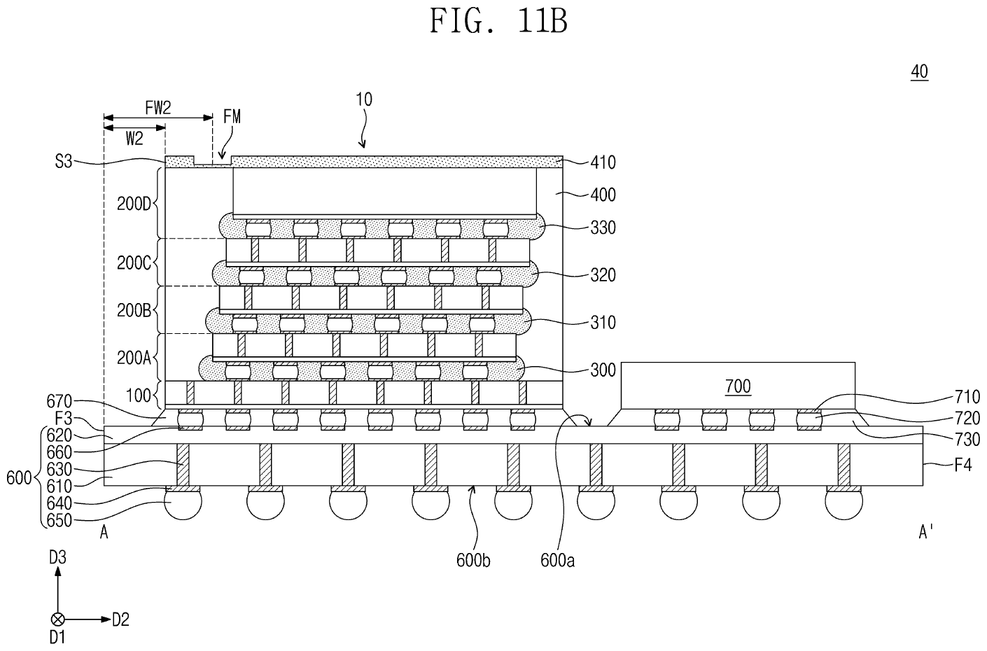

FIG. 10 is a plan view illustrating a semiconductor package according to an embodiment of the inventive concept. FIGS. 11A and 11B are sectional views illustrating a semiconductor package according to an embodiment of the inventive concept, taken along a line A-A′ of FIG. 10. For concise description, a previously described element may be identified by the same reference number without repeating an overlapping description thereof.

Referring to FIGS. 10, 11A, and 11B, a semiconductor package 40 may include a first substrate 600 as well as a unit chip package 10 and a base chip 700, which are mounted on the first substrate 600.

The first substrate 600 may be an interposer substrate. The first substrate 600 may include a module substrate 610, a plurality of penetration electrodes 630 penetrating the module substrate 610, and an interconnection layer 620 on the module substrate 610. In an embodiment, the module substrate 610 may be a silicon substrate. The penetration electrodes 630 may be horizontally spaced apart from each other (D2 direction) in the module substrate 610, and each of the penetration electrodes 630 may penetrate or extend through the module substrate 610. The penetration electrodes 630 may be formed of or include one or more metallic materials (e.g., copper (Cu). The interconnection layer 620 may include metal patterns electrically connected to the penetration electrodes 630.

The first substrate 600 may have a top surface 600a and a bottom surface 600b, which are opposite to each other in the third direction D3, and the interconnection layer 620 may be adjacent to the top surface 600a. The bottom surface 600b of the first substrate 600 may correspond to a surface of the module substrate 610. Each of the penetration electrodes 630 may extend from the interconnection layer 620 toward the bottom surface 600b.

Lower conductive pads 640 may be disposed on the bottom surface 600b of the first substrate 600. The lower conductive pads 640 may be spaced apart from each other in a direction (e.g., the second direction D2) parallel to the bottom surface 600b of the first substrate 600, and each of the penetration electrodes 630 may be connected to a corresponding one of the lower conductive pads 640. The lower conductive pads 640 may be formed of or include one or more conductive materials (e.g., metallic materials).

First connection bumps 650 may be disposed on the bottom surface 600b of the first substrate 600 and may be electrically connected to the lower conductive pads 640, respectively. The first connection bumps 650 may be disposed on the lower conductive pads 640, respectively. The first connection bumps 650 may include a conductive material and may be provided in the form of at least one of solder balls, bumps, and/or pillars.

Upper conductive pads 660 may be disposed adjacent to the top surface 600a of the first substrate 600. The upper conductive pads 660 may be spaced apart from each other in a direction (e.g., the second direction D2) parallel to the top surface 600a of the first substrate 600. The upper conductive pads 660 may be electrically connected to the metal patterns in the interconnection layer 620 and may be electrically connected to the penetration electrodes 630 through the metal patterns. The upper conductive pads 660 may be formed of or include one or more conductive materials (e.g., metallic materials).

The unit chip package 10 and the base chip 700 may be mounted on the top surface 600a of the first substrate 600. The unit chip package 10 and the base chip 700 may be spaced apart from each other in a direction (e.g., the second direction D2) parallel to the top surface 600a of the first substrate 600. In an embodiment, the unit chip package 10 may be the semiconductor package 10 described with reference to FIGS. 1, 2A, and 2B. In this case, the lower semiconductor chip 100 of the unit chip package 10 may be mounted on the top surface 600a of the first substrate 600, and the lower bumps 150 of the lower semiconductor chip 100 may be connected to corresponding ones of the upper conductive pads 660 of the first substrate 600. The unit chip package 10 may be electrically connected to the interconnection layer 620 of the first substrate 600 through the lower bumps 150 and the corresponding upper conductive pads 660.

A process of accurately mounting the unit chip package 10 on the first substrate 600 may include measuring a distance between the vision layer 410 and the first substrate 600. In detail, the first substrate 600 may have a first side surface F1 and a second side surface F2, which are opposite to each other in the first direction D1, and a third side surface F3 and a fourth side surface F4, which are opposite to each other in the second direction D2. The vision layer 410 of the unit chip package 10 may have the first to fourth side surfaces S1 to S4, as described with reference to FIGS. 1, 2A, and 2B. In an embodiment, a distance W1 between the first side surface F1 of the first substrate 600 and the first side surface S1 of the vision layer 410 in the first direction D1 may be measured. In addition, a distance W2 between the third side surface F3 of the first substrate 600 and the third side surface S3 of the vision layer 410 in the second direction D2 may be measured. Accordingly, it may be possible to precisely find the position of the unit chip package 10 to be mounted on the first substrate 600. In addition, it may be possible to precisely measure the heights of the top surface of the vision layer 410 and the top surface 600a of the first substrate 600 and thereby to accurately mount the unit chip package 10 on the first substrate 600.

In an embodiment, the process of accurately mounting the unit chip package 10 on the first substrate 600 may include measuring a distance between the reference mark FM and the first substrate 600. For example, the process may be performed by measuring the distance between the reference mark FM and the first substrate 600 in the horizontal direction D1 or D2 after accurately examining the position of the reference mark FM. In detail, a distance FW1 between a center point of the reference mark FM and the first side surface F1 of the first substrate 600 in the first direction D1 may be measured. In addition, a distance FW2 between the center point of the reference mark FM and the third side surface F3 of the first substrate 600 in the second direction D2 may be measured. Accordingly, it may be possible to precisely find the position of the unit chip package 10 to be mounted on the first substrate 600.

In an embodiment, although not shown, if the first substrate 600 includes the reference mark, the distances between the reference mark of the first substrate 600 and the side surfaces S1-S4 of the vision layer 410 in the horizontal direction D1 or D2 may be measured. In addition, the distance between the reference mark of the first substrate 600 and the reference mark FM on the vision layer 410 in the horizontal direction D1 or D2 may be measured. The same method may be used to find the position of the unit chip package 10 to be mounted on the first substrate 600.

A first under-fill layer 670 may be interposed between the lower semiconductor chip 100 of the unit chip package 10 and the first substrate 600 and may be on and at least partially cover the lower bumps 150 of the lower semiconductor chip 100. The first under-fill layer 670 may include an insulating polymer material (e.g., an epoxy resin).

The base chip 700 may be spaced apart from the unit chip package 10 in a horizontal direction. The base chip 700 may be mounted to be horizontally spaced apart (D2 direction) from the lower semiconductor chip 100 of the unit chip package 10. For example, the base chip 700 may be mounted to be spaced apart from the lower semiconductor chip 100 of the unit chip package 10 in the second direction D2. The base chip 700 may include base chip pads 710, which are provided on a surface of the base chip 700, and base bumps 720, which are electrically connected to the base chip pads 710, respectively. The base bumps 720 may be respectively electrically connected to the upper conductive pads 660 of the first substrate 600. The base chip 700 may be electrically connected to the interconnection layer 620 of the first substrate 600 through the base bumps 720 and the corresponding upper conductive pads 660.

A base under-fill layer 730 may be interposed between the base chip 700 and the first substrate 600 and may be on and at least partially cover the base bumps 720 of the base chip 700. The base under-fill layer 730 may include an insulating polymer material (e.g., an epoxy resin).

The unit chip package 10 and the base chip 700 may be electrically connected to each other through the metal patterns, which are provided in the interconnection layer 620 of the first substrate 600. In an embodiment, the unit chip package 10 may include a high bandwidth memory (HBM) chip, and the base chip 700 may be a memory chip, a logic chip, an application processor (AP) chip, or a system-on-chip (SOC).

According to an embodiment of the inventive concept, a vision layer may be used to easily recognize a relative position between a semiconductor package and an interposer substrate. Thus, it may be possible to accurately find the position of the semiconductor package to be mounted on the interposer substrate. In addition, the vision layer may include an electromagnetic interference shielding material and/or a thermally conductive material. Thus, it may be possible to improve the heat-dissipation property and to realize the stable electromagnetic interference shielding property. In addition, because, in some embodiments, the vision layer covers the entire top surface of the semiconductor package, a semiconductor package with an aesthetically improved appearance may be provided.

In addition, by using a reference mark disposed on the vision layer, it may be possible to accurately find the position of the semiconductor package to be mounted on the interposer substrate.

Accordingly, a semiconductor package with high reliability and a method of fabricating the same may be provided.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a lower semiconductor chip;
a plurality of semiconductor chips stacked on the lower semiconductor chip in a first direction perpendicular to a top surface of the lower semiconductor chip;
non-conductive layers between the lower semiconductor chip and a lowermost one of the semiconductor chips and between the semiconductor chips;
a mold layer on the semiconductor chips and the non-conductive layers; and
a vision layer on the mold layer,
wherein the vision layer comprises a metallic material, and
wherein a bottom surface of the vision layer is in contact with a top surface of an uppermost one of the semiconductor chips and a top surface of the mold layer.

2. The semiconductor package of claim 1, further comprising a reference mark on the vision layer.

3. The semiconductor package of claim 2, wherein the reference mark is adjacent to an edge of the vision layer, when the semiconductor package is viewed in a plan view.

4. The semiconductor package of claim 1, wherein the vision layer comprises an electromagnetic interference shielding material.

5. The semiconductor package of claim 1, wherein the vision layer comprises a thermally conductive material.

6. The semiconductor package of claim 1, wherein side surfaces of the vision layer and side surfaces of the mold layer are aligned to each other in the first direction.

7. The semiconductor package of claim 1, wherein the top surface of the mold layer is coplanar with the top surface of the uppermost one of the semiconductor chips.

8. A semiconductor package, comprising:
a first substrate;
a unit chip package on the first substrate; and
a base chip on the first substrate and spaced apart from the unit chip package,
wherein the base chip is electrically connected to the first substrate through base chip pads and base bumps,
wherein the unit chip package comprises:
a lower semiconductor chip;
a plurality of semiconductor chips stacked on the lower semiconductor chip in a first direction perpendicular to a top surface of the lower semiconductor chip;
non-conductive layers between the semiconductor chips, respectively;
a mold layer on the semiconductor chips and the non-conductive layers; and
a vision layer on the mold layer,
wherein a bottom surface of the vision layer is in contact with a top surface of an uppermost one of the semiconductor chips, and
wherein side surfaces of the first substrate are spaced apart from side surfaces of the vision layer.

9. The semiconductor package of claim 8, wherein the vision layer comprises at least one of a thermally conductive material or an electromagnetic interference shielding material.

10. The semiconductor package of claim 8, wherein the unit chip package further comprises a reference mark on the vision layer.

11. The semiconductor package of claim 10, wherein the reference mark is spaced apart from the side surfaces of the first substrate.

12. The semiconductor package of claim 8, wherein the side surfaces of the vision layer are aligned to side surfaces of the mold layer in the first direction.

13. A semiconductor package, comprising:
a lower semiconductor chip;
a plurality of semiconductor chips stacked on the lower semiconductor chip in a first direction perpendicular to a top surface of the lower semiconductor chip;
a plurality of bumps between the semiconductor chips that electrically connect the semiconductor chips to each other;
non-conductive layers between the semiconductor chips, each of the non-conductive layers being between corresponding ones of the bumps, which are provided between adjacent ones of the semiconductor chips in the first direction;
a mold layer on the semiconductor chips and the non-conductive layers; and
a vision layer on the mold layer,
wherein the vision layer comprises a metallic material,
wherein a bottom surface of the vision layer is in contact with a top surface of a lowermost one of the semiconductor chips and a top surface of the mold layer,
wherein each of the semiconductor chips comprises penetration electrodes, and
wherein the semiconductor chips are electrically connected to each other through the penetration electrodes and the bumps.

14. The semiconductor package of claim 13, further comprising a reference mark on the vision layer,
wherein the reference mark is adjacent to an edge of the vision layer, when the semiconductor package is viewed in a plan view.

15. The semiconductor package of claim 13, wherein side surfaces of the vision layer and side surfaces of the mold layer are aligned to each other in the first direction.

16. The semiconductor package of claim 13, wherein each of the non-conductive layers comprises a protruding portion protruding from side surfaces of adjacent ones of the semiconductor chips.

17. The semiconductor package of claim 16, wherein the protruding portions of the non-conductive layers are spaced apart from each other in the first direction.

18. The semiconductor package of claim 13, further comprising additional bumps between the lowermost one of the semiconductor chips and the lower semiconductor chip,
wherein the lower semiconductor chip comprises lower penetration electrodes, and
wherein the lower semiconductor chip is electrically connected to the semiconductor chips through the lower penetration electrodes and the additional bumps.

19. The semiconductor package of claim 13, wherein the top surface of the mold layer is coplanar with a top surface of an uppermost one of the semiconductor chips.

20. The semiconductor package of claim 13, further comprising:
a first substrate; and
a base chip mounted on the first substrate,
wherein the lower semiconductor chip is mounted on the first substrate and is spaced apart from the base chip, and
wherein side surfaces of the first substrate are spaced apart from side surfaces of the vision layer.
